(19) United States
(12) Patent Application Publication
(10) Pub. No.: US 2010/0308327 A1
(43) Pub. Date: Dec. 9, 2010

(54) ZnO-BASED SUBSTRATE, METHOD FOR PROCESSING ZnO-BASED SUBSTRATE, AND ZnO-BASED SEMICONDUCTOR DEVICE

(76) Inventors: Ken Nakahara, Kyoto (JP); Shunsuke Akasaka, Kyoto (JP); Masashi Kawasaki, Miyagi (JP); Akira Ohtomo, Miyagi (JP); Atsushi Tsukazaki, Miyagi (JP)

Correspondence Address: RABIN & Berdo, PC, 1101 14TH STREET, NW, SUITE 500, WASHINGTON, DC, 20005, US

(21) Appl. No.: 12/865,550

(22) PCT Filed: Jan. 30, 2009
(86) PCT No.: PCT/JP2009/051593

§ 371 Date: Jul. 30, 2010

(30) Foreign Application Priority Data
Jan. 31, 2008 (JP) 2008-021503

(51) Int. Cl. H01L 29/22; H01L 21/36

(52) U.S. Cl. 257/43; 438/104; 257/E29.095; 257/E21.461

(57) ABSTRACT

Provided are a ZnO-based substrate having a high-quality surface suitable for crystal growth, a method for processing the ZnO-based substrate, and a ZnO-based semiconductor device. The ZnO-based substrate is formed such that any one of a carboxyl group and a carbonate group is substantially absent in a principal surface on a crystal growth side. Also, in order for a carboxyl group or a carbonate group to be substantially absent, any one of oxygen radicals, oxygen plasma and ozone is brought into contact with the surface of the ZnO-based substrate before the crystal growth is started. Consequently, cleanness of the surface of the ZnO substrate is enhanced, thereby enabling fabrication of a high-quality ZnO-based thin film on the substrate.

### TECHNICAL FIELD

The present invention relates to a ZnO-based substrate suitable for crystal growth of a ZnO-based thin film and the like, a method for processing the ZnO-based substrate, and a ZnO-based semiconductor device using these.

### BACKGROUND ART

ZnO-based semiconductors have been expected to be applied to ultraviolet LEDs used as light sources for illuminations, backlights and the like, as well as to high-speed electronic devices, surface acoustic wave devices, and so forth. A ZnO-based semiconductor has drawn attention to its versatility, large light emission potential and the like. However, no significant development has been made on such a ZnO-based semiconductor as a semiconductor device material. The largest obstacle is that p-type ZnO cannot be obtained because of difficulty in acceptor doping.

In recent years, however, as shown in Non-patent Documents 1 and 2, technological advancement has made it possible to obtain p-type ZnO and also to observe light emission. These achievements are valuable as they have demonstrated the usability of ZnO. Nonetheless, use of a special and insulative ScAlMgO₄ substrate as well as pulsed laser deposition which is a method unsuitable for a large area is disadvantageous in term of industrial application.

The best way to solve these problems is to use a ZnO substrate. ZnO substrates have already been commercially available, and this is advantageous for ZnO-based devices compared to GaN. ZnO substrates seem to have very good prospects when one considers only some aspects such as so-far-achieved success in producing ZnO substrates of 3 inch and a half width of an X-ray diffraction peak.

However, a substrate surface is the most problematic part in the case of fabricating a device demonstrating a new function by stacking films different not only in dopant but in composition, as in cases of many compound semiconductors. For compound semiconductors, a thin film is often grown using a vapor growth method for its superior controllability. In this case, crystals of atoms or molecules supplied from vapor are grown on the basis of the information on the substrate surface on which they land. Thus, even when the bulk has a high quality, the substrate is totally meaningless if the surface does not have a sufficiently high quality.

For the quality of the surface, flatness is generally considered in most cases. Poor flatness in a substrate surface leads to poor flatness in a film stacked thereon, which in turn works as resistance to carriers moving through the thin film. In addition, the higher the layer in a stacked structure becomes, the larger the surface roughness becomes. Such surface roughness is likely to cause a problem of an uneven etching depth. The surface roughness is also likely to cause a problem of anisotropic crystal surface growth. Thus, a semiconductor device is likely to have a difficulty in demonstrating a desired function.

### Non-patent Document 1: A. Tsukazaki et al., JJAP 44 (2005) L643

### Non-patent Document 2: A. Tsukazaki et al., Nature Material 4 (2005) 42

### Non-patent Document 3: Applied Surface Science 237 (2004) p. 336-342/Ulrike Diebold et al.

### Non-patent Document 4: Applied Physics Letters 89 (2006) p. 182111-182113/S. A. Chevtchenko et al.

### DISCLOSURE OF THE INVENTION

### Problems to be Solve by the Invention

Meanwhile, a substrate cleaning process to obtain a clean surface is performed as a process to improve the quality of the substrate surface other than flatness. However, in case of a ZnO-based substrate, a flat and clean surface suitable for epitaxial growth cannot be obtained by common polishing such as wet etching which brings out a clean surface (see Non-patent Documents 3 and 4, for example). To obtain a surface suitable for epitaxial growth, used is CMP (Chemical Mechanical Polishing) which is well known as a planarizing process.

In a method using CMP, for example, chemical mechanical polishing is performed while supplying alkaline aqueous polishing slurry, in which colloidal silica is diffused, between a polishing pad of a rotary single-side polishing machine or the like and a process target such as a ZnO substrate. The alkaline aqueous polishing slurry is used as described above because colloidal silica (small SiO₂ particles having a diameter of approximately 5 nm) used as the polishing agent aggregates unless it is in alkaline solution. When polished with colloidal silica, however, the surface of the ZnO substrate is exposed to the alkaline aqueous solution in the slurry, whereby Zn(OH)_{X}, which is a hydroxide of Zn, is formed in the surface of the ZnO-based substrate in the form of gel. In addition, due to the gel form, colloidal silica is taken into the gel Zn(OH)_{X} so that silica as a component of the polishing agent comes to remain in the ZnO surface.

As the concentration of silica becomes higher, Si diffused in a ZnO-based film accordingly increases. Thus, Si serving as a donor becomes a problem in a case of conversion into p type or of fabricating a device. Meanwhile, the formation of a hydroxide in the surface of the ZnO-based substrate develops defects in a crystalline film formed on the ZnO-based substrate. This brings about an adverse effect such as an increase in defect density.

In this respect, we proposed removal of silica and a hydroxide in the surface of the ZnO-based substrate, in Japanese Patent Application Publication No. 2007-171132 having been filed. However, it was found desirable to remove impurities deposited on the surface of the ZnO-based substrate including not only the silica and hydroxide, but also those besides the silica and hydroxide in fabrication of a highly-accurate semiconductor device.

The present invention has been made to solve the above mentioned problems and has an object to provide a ZnO-based substrate having a high-quality surface suitable for crystal growth, a method for processing the ZnO-based substrate, and a ZnO-based semiconductor device.

### Means for Solving the Problems

In order to achieve the above object, a ZnO-based substrate of the present invention is configured such that any one of a carboxyl group and a carbonate group is substantially absent in a principal surface on a side where crystal growth takes place.

Additionally, in the above configuration, in X-ray photoelectron spectroscopy of a principal surface on a side where crystal growth takes place, an excitation energy peak of a is core electron of a carbon atom may not substantially appear within a range from 288 to 290 eV.

Moreover, in the above configuration, in X-ray photoelectron spectroscopy of a principal surface on a side where crystal growth takes place, a peak excitation energy distribution of a 1s core electron of a carbon atom in a range from 284 to 286 eV may spread from a peak energy as a center with a skirt on a high energy side that is not wider than a skirt on a low energy side.

Further, in the above configuration, the ZnO-based substrate may be a Mg_{X}Zn_{1-X}O substrate (0≦X≦1).

Furthermore, in the above configuration, the principal surface where the crystal growth takes place may have a C-plane, and a projection axis obtained by projecting a normal line to the principal surface onto a plane of an m-axis and a c-axis of crystal axes of the substrate may be inclined toward the m-axis within a range not larger than 3°.

Also, in the above configuration, a projection axis obtained by projecting a normal line to the principal surface onto a plane of an a-axis and a c-axis of crystal axes of the substrate may be inclined toward the a-axis at an angle Φₐ, a projection axis obtained by projecting the normal line to the principal surface onto a plane of an m-axis and the c-axis at the principal surface may be inclined toward the m-axis at an angle Φₘ, and

the Φₐ may satisfy

70≦{π−(180/π)arctan(tan(πΦₐ/180)/tan(πΦₘ/180))}≦110.

In addition, a ZnO-based semiconductor device of the present invention has a configuration in which a ZnO-based thin film is stacked on the ZnO-based substrate in any configuration described above.

Moreover, in the above configuration, the ZnO-based thin film may be a stacked body in which a p-type MgZnO layer is stacked on an undoped ZnO layer.

Further, in the above configuration, the ZnO-based thin film may be a stacked body in which a n-type MgZnO layer, an active layer and a p-type MgZnO layer are stacked in this order, the active layer obtained by alternately arranging MgZnO and ZnO.

Furthermore, a method for processing a ZnO-based substrate includes the step of bringing any one of an oxygen radical, oxygen plasma and ozone into contact with a principal surface where crystal growth takes place, before the crystal growth is started.

### Effects of the Invention

The ZnO-based substrate of the present invention is configured such that any one of a carboxyl group and a carbonate group is substantially absent in a principal surface on a side where crystal growth takes place. This makes it possible to enhance the cleanness of the surface of the ZnO-based substrate and therefore to fabricate a high-quality ZnO-based thin film on the substrate. Meanwhile, in order for a carboxyl group or a carbonate group to be substantially absent, any one of oxygen radicals, oxygen plasma and ozone is brought into contact with the surface of the ZnO-based substrate before the crystal growth is started. This cleans the surface of the ZnO-based substrate and therefore improves the quality of the substrate surface.

### BRIEF DESCRIPTION OF THE DRAWINGS

FIG. 1 is a graph illustrating XPS signal intensity distributions of 1s core electrons in carbon atoms in XPS measurement performed after predetermined processes are performed on the C-planes of ZnO substrates.

FIG. 2 is a graph illustrating XPS signal intensity distributions of 1s core electrons in carbon atoms in XPS measurement performed after predetermined processes are performed on the C-planes of ZnO substrates.

FIG. 3 is a graph illustrating states of core electrons of oxygen of ZnO before and after hydrochloric acid etching.

FIG. 4 is a graph illustrating states of core electrons of carbon in a ZnO surface before and after hydrochloric acid etching.

FIG. 5 is a graph illustrating states of core electrons of carbon in a ZnO surface.

FIG. 6 is a diagram illustrating a surface of a ZnO substrate on which an abnormal diffraction pattern is measured in RHHED measurement, and also a diagram showing the surface after hydrochloric acid etching.

FIG. 7 is a diagram illustrating the surface of a film formed on a Mg_{X}Zn_{1-X}O substrate of a case where a line normal to the substrate principal surface has an off angle in the m-axis direction.

FIG. 8 is a diagram illustrating the surface of a film formed on a Mg_{X}Zn_{1-X}O substrate of a case where the line normal to the substrate principal surface has an off angle in the m-axis direction.

FIG. 9 is a diagram illustrating a surface of a ZnO substrate of a case where a line Z normal to the substrate principal surface has an off angle only in the m-axis direction.

FIG. 10 is a diagram illustrating the relationship between the line normal to the substrate principal surface and the c axis, m-axis and a-axis as the crystal axes of the substrate.

FIG. 11 is a diagram illustrating how the line normal to the surface of the ZnO substrate is inclined and also the relationship between each step edge and the m-axis.

FIG. 12 is a diagram illustrating states of surfaces of a Mg_{X}Zn_{1-X}O substrate differing from one another in the off angle of the line normal to the substrate principal surface in the a-axis direction.

FIG. 13 is a diagram illustrating an example of a ZnO-based semiconductor device formed by using a ZnO-based substrate of the present invention.

### EXPLANATION OF REFERENCE NUMERAL

1 ZnO substrate

### BEST MODES FOR CARRYING OUT THE INVENTION

First of all, a ZnO-based substrate is a substrate mainly containing ZnO and is formed of ZnO or a compound containing ZnO. Besides one containing ZnO, a specific example of the substrate includes one containing any one of oxides of: a group IIA element and Zn; a group IIB element and Zn; a group IIA element, a group IIB element and Zn. Mix crystals such as Mg_{X}Zn_{1-X}O in which Mg is mixed in order to widen the bandgap are also included.

In this embodiment, a Mg_{X}Zn_{1-X}O substrate (0≦X≦1) was used, and a configuration to form this substrate's crystal growth side surface as a suitable surface for crystal growth was figured out. Studies were carried out as follows using a ZnO substrate whose X is 0 among the Mg_{X}Zn_{1-X}O substrates (0≦X<1).

FIG. 6(b) is an image of the ZnO substrate surface where an abnormal diffraction pattern was measured in RHEED (reflection high energy electron diffraction) measurement. The image was captured in a field of view of 1 μm×1 μm using an AMF (atomic force microscope). It can be seen from the image that the substrate surface includes many deposits and is extremely uneven. Meanwhile, FIG. 6(a) is an image of the ZnO substrate surface of FIG. 6(b) after performing etching thereon with hydrochloric acid solution for 15 seconds. The image was captured in a field of view of 1 μm×1 μm using the AMF (atomic force microscope). As the image shows, etching with hydrochloric acid solution allows removal of impurities such as a hydroxide and silica so that a normal diffraction pattern may be indicated even in RHEED measurement.

We, however, found that the substrate surface could not be completely cleaned only by etching with hydrochloric acid solution. For example, when left exposed to the atmosphere, a wafer or the like is contaminated due to deposition of C (carbon) in the atmosphere. It was found that in a case of the ZnO substrate, deposition of CO₃ groups (carbonate groups) or COOH groups (carboxyl groups) thereon causes an abnormality in the substrate surface. Since a carbonate group and a carboxyl group are polar molecules and a C-plane ZnO substrate itself has a polar structure, chemical adsorption of hydrogen bonding type is likely to occur. Heating in vacuo in the presence of these adsorbed molecules sometimes causes an abnormality, which in turn deteriorates the flatness of a ZnO-based thin film obtained through crystal growth on a principal surface of the ZnO substrate. So, in order to improve the quality of the principal surface of the ZnO substrate, carbonate groups or carboxyl groups derived from carbon need to be substantially absent.

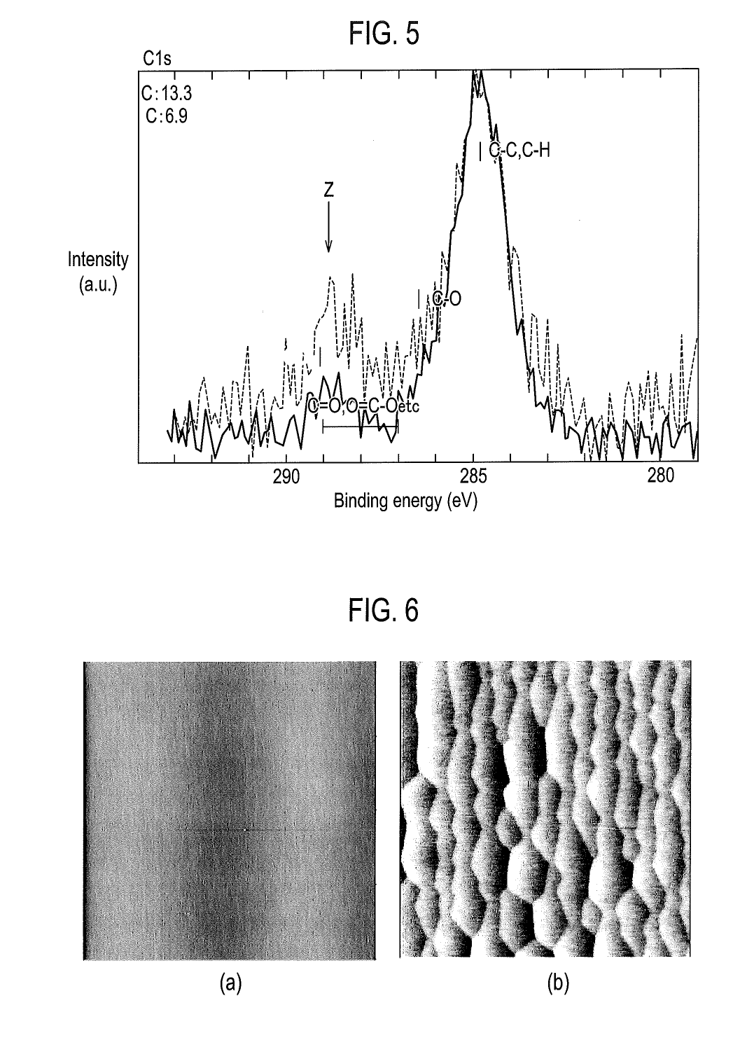

FIG. 5 shows the binding energy of the orbital of a 1s core electron of C (carbon) in the ZnO substrate surface contaminated with carbon. This data was obtained by checking the state of the ZnO substrate surface through XPS (X-ray Photoelectron Spectroscopy) measuring in the vicinity of an excitation energy peak of the 1s core electron of a C (carbon) atom. Note that the vertical axis is normalized using the peak intensity of the main peak, which is present at 285 eV. The horizontal axis indicates the binding energy (unit: eV) while the vertical axis indicates the XPS signal intensity (any unit) at the corresponding binding energy. The data with a dashed line represents a case where the ratio of C (carbon) to the constituent elements of the ZnO substrate surface is 13.3%, while the data with a solid line represents a case where the ratio of C is 6.9%. A peak of the binding energy of a C1s electron in a case of C—C and C—H exist approximately around 285 eV. On the other hand, a peak of the binding energy of a carbonate group or a carboxyl group, which are carbon compounds, appears at a point indicated by an arrow Z in a case of C═O or O═C—O bonding. The energy peak is approximately around 289 eV.

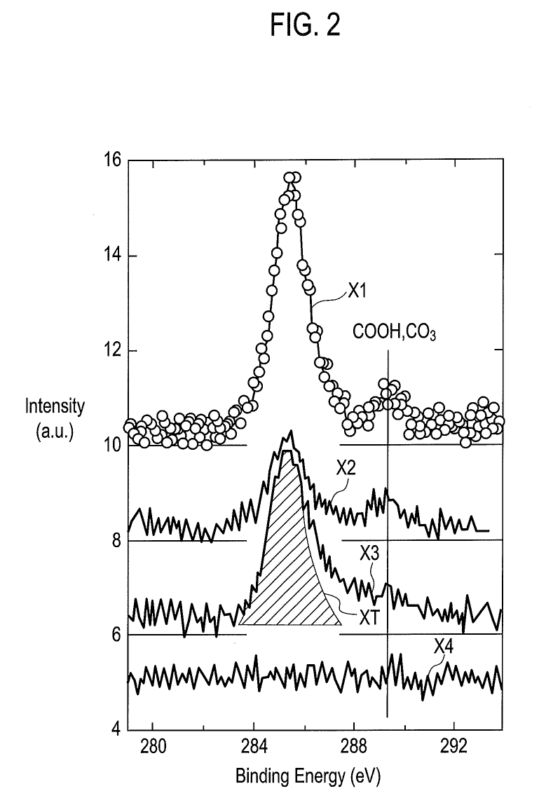

Meanwhile, FIG. 2 is one obtained by checking mutually different states of a crystal face in the principal surface of the ZnO substrate through XPS (X-ray Photoelectron Spectroscopy) and shows a comparison among the XPS peak intensities of C1s electrons in a case of C—C and C—H bonding. For measured curves X1 to X4, +C planes of the ZnO substrate are cut out and subjected to mirror polishing, and then the substrate surfaces differing from one another in terms of the process performed on the surfaces after the mirror polishing were measured through XPS. The horizontal axis indicates the binding energy (unit: eV) while the vertical axis indicates the XPS signal intensity at the corresponding binding energy.

First, X1 represents the binding energy of a 1s core electron of a carbon atom in the ZnO substrate surface whose surface image is defined as abnormal as a result of reflection high energy electron diffraction (RHEED) measurement on the ZnO substrate surface. X1 represents a ZnO substrate whose surface is contaminated with carbon and includes CO₃ groups (carbonate groups) or COOH groups (carboxyl groups) produced and deposited thereon. For this reason, there is a peak appearing around 289 eV.

As to X3, the ZnO substrate surface was subjected to XPS measurement as it was without performing any process thereon immediately after mirror polishing. X2 represents a measurement result obtained by subjecting the surface of the ZnO substrate used for X3 only to etching with HCl (hydrochloric acid) solution for 15 seconds, followed by XPS measurement. Meanwhile, sputtering of a surface with Ar ions is a method commonly employed in surface science researches to obtain a clean surface. So, X4 is a measurement result obtained by subjecting the surface of the ZnO substrate used for X3 to sputtering with Ar ions by approximately 30 mm under high vacuum inside a XPS apparatus, followed by XPS measurement in the condition where the high vacuum state is maintained.

The following illustrates the specification of the apparatus used for the XPS measurement: the measurement apparatus is Quantera SXM of Physical Electronics, Inc; the X-ray source is monochromated Al X-ray source (1486.6 eV); the detection region is 100 μm in diameter; and the detection depth is 4 nm to 5 nm (take off angle: 45°).

There is no energy peak appearing at all in X4 which is a measured curve obtained after the sputtering is performed. This indicates that no carbon-based deposit is left in the surface of the ZnO substrate. The cleaning of the substrate surface by sputtering therefore makes it possible to achieve a quite large effect. However, sputtering with Ar ions or the like is a technique that applies physical impact on the surface and therefore puts the chemical bond between Zn and O into an abnormal bonding state. This leads to breakage of the chemical bond between Zn and O. Thus, this method is not desirable.

Meanwhile, as the curve of X2 shows, acid wet etching such as the hydrochloric acid etching is considered to contribute more to the cleaning for obtaining a clean surface of the ZnO substrate, as the acid level of the acid wet etching increases. Particularly, we have already found that the acid level of the etching solution needs to be set at a certain level in order to remove deposits such as silica and particles from the substrate surface. Details of such are in Japanese Patent Application Publication No. 2007-171132 having been filed.

However, like X1, there is also a small peak appearing approximately around 289 eV in X2 which is a XPS measurement result obtained after etching the surface of the ZnO substrate with HCl (hydrochloric acid) solution for 15 seconds. This means that etching with hydrochloric acid solution may remove impurities such as silica and a hydroxide from the surface of the ZnO substrate but may not remove impurities such as carbonate groups and carboxyl groups.

Meanwhile, looking at the energy peak distribution curve of X3, one may notice that the skirt of the distribution is spreading wider toward a high energy side than toward a low energy side in terms of the binding energy, from a high peak value present approximately around 285 eV as a center. In other words, with the peak value (approximately 285 eV) as a center, the peak width on the high energy side is larger than the peak width on the low energy side.

A curve XT is illustrated inward of the curve X3 by a shaded area. The curve XT is illustrated as almost symmetrical with respect to the peak value of approximately 285 eV as its center. This is considered the original peak distribution curve of the binding energy of carbon. Moreover, like X2, a remarkable peak related to a carbonate group or a carboxyl group is appearing approximately around 289 eV due to the etching with hydrochloric acid solution. With these taken into consideration, it is possible to consider that in X3, the skirt of distribution spreads wider toward the high energy side than toward the low energy side in terms of the binding energy because the curve XT is combined with a distribution curve centered on the small peak at approximately 289 eV.

Thus, even in the case of X3 where the ZnO substrate surface was subjected to XPS measurement as it was without performing any process thereon immediately after mirror polishing, it may be considered that carbonate groups or carboxyl groups were already produced and deposited on the surface so that the skirt of distribution spread wider toward the high energy side.

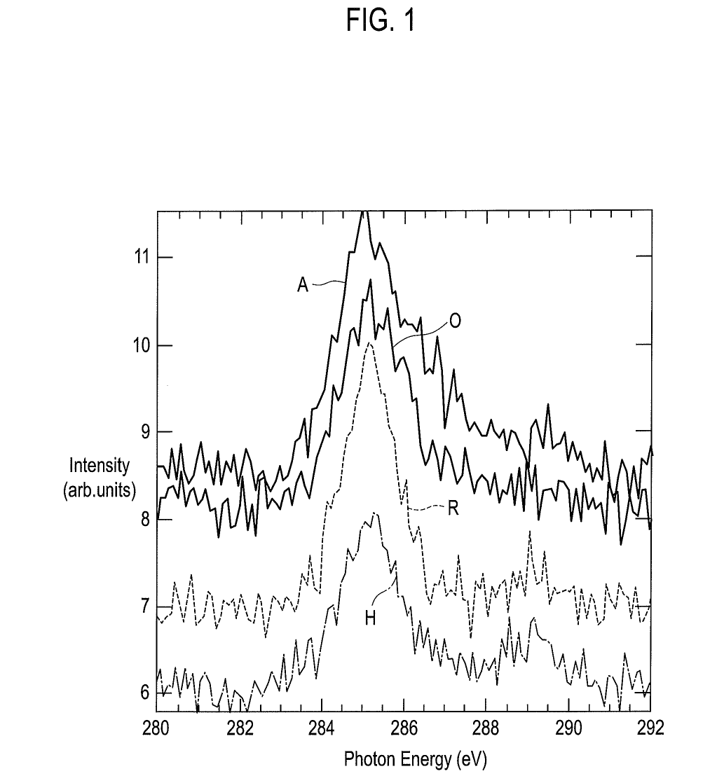

Note that in the ZnO substrate surface, to eliminate substantially completely the presence of carbonate groups and carboxyl groups derived from carbon is equivalent to a situation where the presence of an excitation energy peak of a 1s core electron of a C atom is found eliminated substantially completely from in a range from 288 to 290 eV in FIGS. 1 and 2 and the like in X-ray photoelectron spectroscopy of the ZnO substrate's principal surface on the side where crystal growth takes place. In addition, to eliminate substantially completely the presence of carbonate groups and carboxyl groups derived from carbon is equivalent also to a situation where the skirt of the peak excitation energy distribution of a 1s core electron of a C atom in a range from 284 to 286 eV spreads from a peak energy as a center with a skirt on a high energy side that is not wider than a skirt on a low energy side.

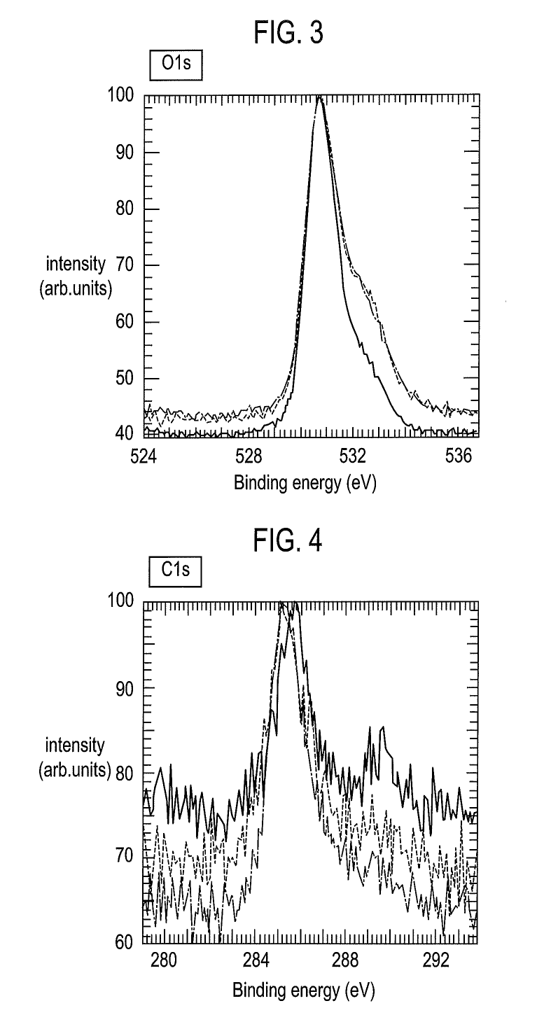

Meanwhile, FIGS. 3 and 4 show what is removed by hydrochloric acid etching among the impurities deposited to the ZnO substrate surface. In both of FIGS. 3 and 4, a curve with a chain line represents a result of XPS measurement performed on a surface of the ZnO substrate as it is without performing any process thereon immediately after mirror polishing. A curve with a dotted line represents a result of XPS measurement performed on a surface of the ZnO substrate subjected to metal deposition for temperature measurement immediately after mirror polishing. A curve with a solid line represents a result of XPS measurement performed on a surface of the ZnO substrate subjected only to hydrochloric acid etching immediately after mirror polishing. Incidentally, the vertical axis is normalized using the peak intensity of 285 eV.

FIG. 3 shows the binding energy of a 1s core electron of oxygen (O) in each of the surfaces of the ZnO substrate, whereas FIG. 4 shows the binding energy of a 1s core electron of carbon (C) in the surface of the ZnO substrate. As can be seen from FIG. 3, after hydrochloric acid etching, there was a decrease in energy intensity as well as in peak width in a range from 532 to 536 eV, indicating that most of OH groups (hydroxyl groups) was removed. However, in a measurement result in FIG. 4, based on the graph of the solid line obtained by XPS measurement after performing hydrochloric acid etching, there is a peak appearing at 289 to 290 eV. This indicates that impurities such as carbonate groups and carboxyl groups have not been removed.

In this respect, means for removing such impurities as carbonate groups and carboxyl groups from the surface of the ZnO substrate will be described based on FIG. 1. FIG. 1 shows a comparison result obtained by performing several types of processes on surfaces of the ZnO substrate, and by performing XPS on the surfaces of the ZnO substrate and comparing the XPS signal intensities of 1s core electrons of carbon atoms in the surfaces.

First of all, a curve denoted by R was obtained by performing XPS measurement of the XPS signal of a 1s core electron of carbon in a +C plane surface of the ZnO substrate as it is was without performing any processes thereon immediately after mirror polishing the surface of the ZnO substrate. H represents the XPS signal of a 1s core electron of carbon in a +C-plane surface of the ZnO substrate subjected only to hydrochloric acid etching after polishing.

Meanwhile, A represents the XPS signal of a 1s core electron of carbon measured after performing an ashing process, i.e., after exposing a surface (+C plane) of the ZnO substrate to oxygen plasma or oxygen radicals. O represents the XPS signal of a 1s core electron of carbon measured after exposing a surface (+C plane) of the ZnO substrate to ozone.

As clear from these, in the curves H and the like, the proportion of a peak present at 289 to 290 eV to a higher peak present approximately around 285 eV is large. In contrast, it can be seen that the proportion of the peak present at 289 to 290 eV is quite small in the case where oxygen plasma or oxygen radicals are brought into contact with the surface of the ZnO substrate (ashing process) or where ozone is brought into contact with the surface of the ZnO substrate. In other words, a significant amount of carbonate groups and carboxyl groups is considered to be removed.

In addition, to expose the surface of the ZnO substrate to any of oxygen radicals, oxygen plasma and ozone prior to performing crystal growth on the ZnO substrate results in oxidation which repairs or stabilizes the chemical bond between Zn and O in the substrate surface on the crystal growth side, thereby bringing about an effect of obtaining a high-quality substrate surface as well.

Next, conditions for a high quality of the surface of the Mg_{X}Zn_{1-X}O substrate (0≦X<1) on the crystal growth side will be discussed from the viewpoint of crystal structure. To be discussed is how to obtain a high-quality substrate surface: including no deposits such as silica and particles as well as carbonate groups, carboxyl groups and the like; being undamaged; and allowing formation of a finely-flat thin film thereon.

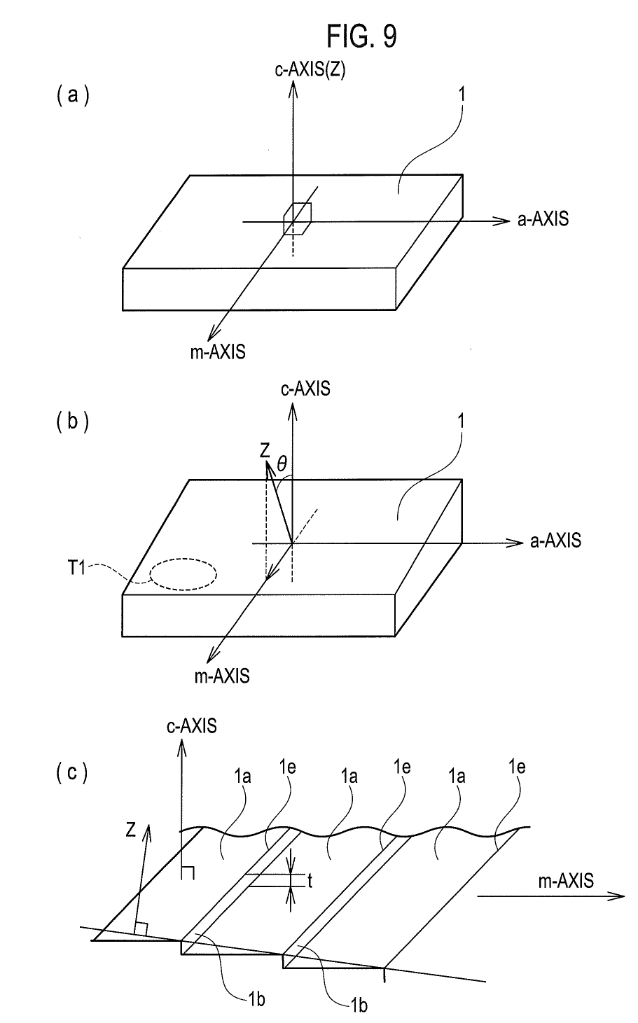

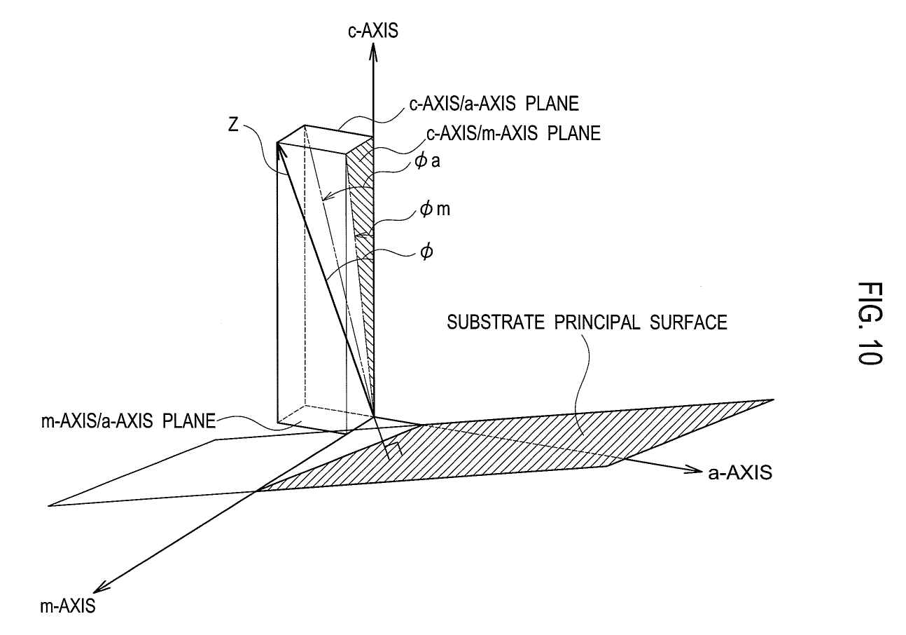

Like GaN, ZnO-based compounds have a hexagonal crystal structure known as Wurtzite. The terms such as the C plane and the a-axis can be expressed by so-called Miller indices. For example, the C plane is expressed as (0001) plane. When a ZnO-based thin film is made to grow on a ZnO-based material layer, the growth is usually performed on the C plane, that is, the (0001) plane. If a C-plane just substrate is used, the direction of the normal line Z to the wafer's principal surface coincides with the c-axis direction, as shown in FIG. 9(a). It is a well-known fact that even if a ZnO-based thin film is made to grow on a C-plane just ZnO substrate, no improvement can be achieved in the flatness of the film. In addition, in a bulk crystal, the direction of the normal line to the wafer's principal surface does not coincide with the c-axis direction unless a cleavage plane that the crystal has is used. In addition, the use of only the C-plane just substrate results in lower productivity.

Accordingly, the direction of the normal line to the principal surface of a ZnO substrate 1 (wafer) is made not to coincide with the c-axis direction. That is, the direction of the normal line Z is inclined from the c-axis of the principal surface of the wafer, so that an off angle is formed between the direction of the normal line Z and the c-axis. As FIG. 9(b) shows, if the normal line Z to the principal surface of the substrate is inclined from the c-axis towards only the m-axis by θ degrees, for example, terrace surfaces 1a and step surfaces 1b are formed as shown in FIG. 9(c), which is an enlarged view of a surface portion (e.g., of an area T1) of the substrate 1. Each of the terrace surfaces 1a is a flat surface. Each of the step surfaces 1b is formed at a portion where there is a level difference portion formed by the inclination. The step surfaces 1b are arranged equidistantly and regularly.

Note that each terrace surface 1a corresponds to the C plane (0001) whereas each step surface 1b corresponds to the M plane (10-10). As FIG. 9(c) shows, the step surfaces 1b thus formed are arranged in the m-axis direction at regular intervals with the widths of the terrace surfaces 1a maintained equal to each other. As FIG. 9(c) shows, the c-axis, which is perpendicular to the terrace surfaces 1a, is inclined from the Z axis by θ°. Step lines 1e, which are the step edges of the step surfaces 1b, are arranged in parallel with each other at intervals each equal to the width of the terrace surface 1a, while maintaining a perpendicular relationship with the m-axis direction.

In this way, if the step surfaces are formed as surfaces corresponding to the M planes, a ZnO-based semiconductor layer formed by crystal growth on a principal surface can be made as a flat film. Although level-difference portions are formed in the principal surface by the step surfaces 1b, each of the flying atoms that come to these level-difference portions is bonded to the two surfaces, that is, one of the terrace surfaces 1a and a corresponding one of the step surfaces 1b. Accordingly, such atoms can be bonded more strongly than the flying atoms that come to the terrace surfaces 1a. Consequently, the flying atoms can be trapped stably by the level-difference portions.

In a surface diffusion process, the flying atoms are diffused within each terrace. Such atoms are trapped at the level-difference portions where the bonding force is stronger or at kink positions that are formed in the level-difference portions. The trapped atoms are taken into the crystal. The kind of crystal growth that progresses in this way is known as a lateral growth, and is a stable growth. Accordingly, if a ZnO-based semiconductor layer is laminated on a substrate with the normal line to the principal surface of the substrate inclined at least in the m-axis direction, the crystal of the ZnO-based semiconductor layer grow around the step surfaces 1b. Consequently, a flat film can be formed.

To put it differently, what are necessary for the fabrication of a flat film is the step lines 1e which are arranged regularly in the m-axis direction and which have a perpendicular relationship with the m-axis direction. If the intervals and the lines of the step lines 1e are improper, the lateral growth described above cannot progress. Consequently, no flat film can be fabricated.

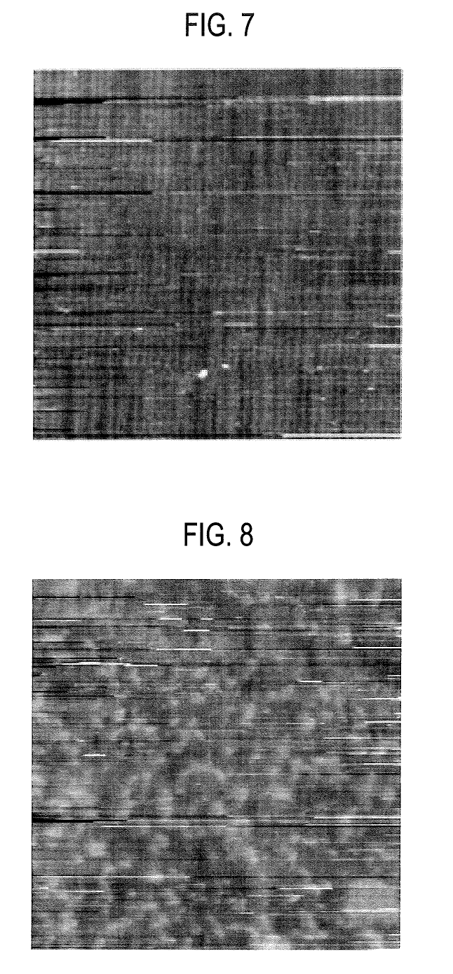

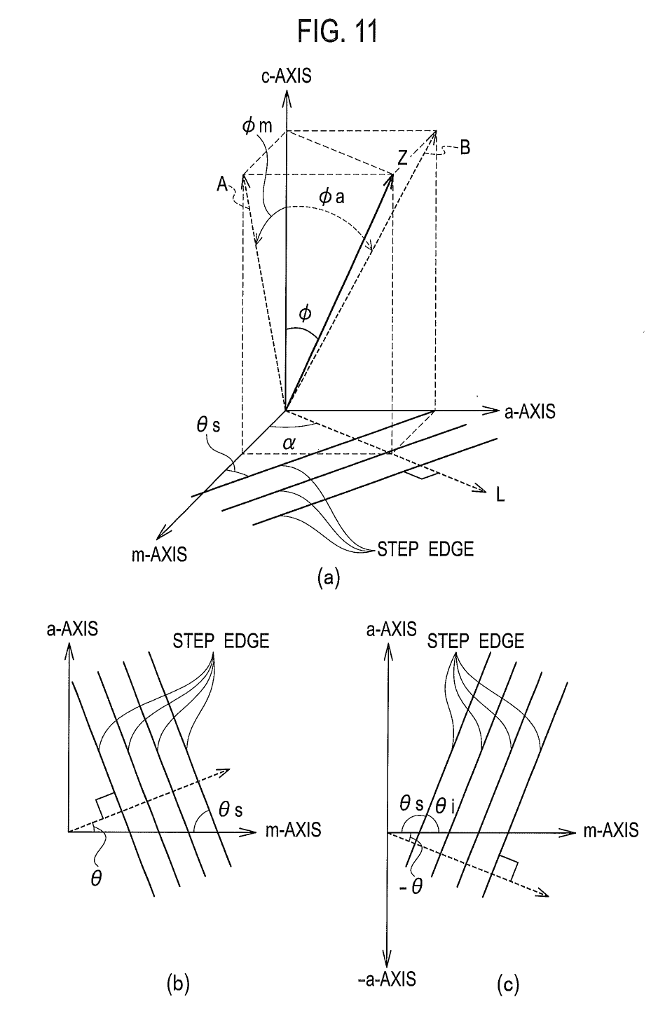

If the inclination angle (off angle) 0 shown in FIG. 9(b) is too large, a step height t of each step surface 1b sometimes becomes too high. This prevents the crystal from growing flatly. So, the off angle in the m-axis direction has to be restricted within a certain angle range. FIGS. 7 and 8 show that the flatness of a growing film varies depending upon the inclination angle in the m-axis direction. FIG. 7 is of a case where the inclination angle θ is 1.5° and where a ZnO-based semiconductor is made to grow on a principal surface of a Mg_{X}Zn_{1-X}O substrate having this off angle. FIG. 8 is of a case where the inclination angle θ is 3.5° and where a ZnO-based semiconductor is made to grow on a principal surface of a Mg_{X}Zn_{1-X}O substrate having this off angle. FIGS. 7 and 8 show images obtained by scanning a 1-μm square area by use of an AFM after the crystal growth. The image of FIG. 7 shows that the widths of the steps are arranged regularly and that the film thus formed is fine. The image of FIG. 8 shows that irregularities are found from place to place and thus the flatness is lost. Accordingly, the inclination angle θ is preferably larger than 0° but is not larger than 3° (0<θ≦3). Thus, the same applies to an inclination angle Φₘ in FIG. 11, and it is most suitable to set the angle larger than 0° but not larger than 3° (0<Φₘ≦3).

As described above, it is most desirable that the direction of the normal line Z to the principal surface of the substrate be inclined from the c-axis only toward the m-axis and that the inclination angle be larger than 0° but not larger than 3°. However, in a practical sense, it is difficult to limit the case to one in which the surface is cut out with the normal line Z inclined only toward the m-axis. As a production technique, it is also necessary to tolerate inclination toward the a-axis and to set the degree of such tolerance. For example, consider a case as shown in FIG. 10 where: the normal line Z to the principal surface of the substrate is inclined from the c-axis of the crystal axes of the substrate at an angle Φ; a projection axis, which is obtained by projecting the normal line Z onto the c-axis/m-axis plane within the Cartesian coordinate system of the c-axis, m-axis, and a-axis of the crystal axes of the substrate, is inclined toward the m-axis at an angle Φₘ; and a projection axis obtained by projecting the normal line Z onto the c-axis/a-axis plane is inclined toward the a-axis at an angle Φₐ.

Like FIG. 10, FIG. 11(a) shows a state where the normal line Z to the principal surface of the substrate is inclined, but in a more easily understandable way regarding the relationship between the normal line Z and the Cartesian coordinate system of the c-axis, m-axis and a-axis. FIG. 11(a) differs from FIG. 10 only in the direction in which the normal line Z to the principal surface of the substrate is inclined. What are meant by Φ, Φₘ and Φₐ remain the same as those in FIG. 10. Moreover, FIG. 11(a) shows a projection axis A obtained by projecting the normal line Z to the principal surface of the substrate onto the c-axis/m-axis plane within the Cartesian coordinate system of the c-axis, m-axis and a-axis, and also shows a projection axis B obtained by projecting the normal line Z onto the c-axis/a-axis plane.

Furthermore, FIG. 11(a) also shows, as a direction L, the direction of a projection axis obtained by projecting the normal line Z to the principal surface of the substrate onto the a-axis/m-axis plane of the Cartesian coordinate system of the c-axis, m-axis and a-axis as the crystal axes of the substrate. Here, terrace surfaces 1c and step surfaces 1d are formed. Each of the terrace surfaces 1c is a flat surface as shown in FIG. 9. Each of the step surfaces 1d is formed at a portion where there is a level difference portion formed by the inclination. Here, each terrace surface corresponds to the C plane (0001). However, unlike FIG. 9, the normal line Z in FIG. 11(a) is inclined at the angle Φ from the c-axis perpendicular to the terrace surface.

Since the direction of the normal line to the principal surface of the substrate is inclined not only toward the m-axis but also toward the a-axis, the step surfaces appear in a diagonal direction. Hence, the step surfaces come to be arranged in the direction L. This state appears as an alignment of step edges extending toward the m-axis as shown in FIGS. 11(a) and 11(b). In this case, the M-plane is a thermally chemically stable plane, so that fine diagonal steps cannot be maintained depending on the inclination angle Φₐ in the a-axis direction. This forms irregularities in the step surfaces 1d, disturbing the alignment of the step edges. As a result, a flat film cannot be formed on the principal surface. The fact that the M-plane is thermally chemically stable was found by the present inventors and described in detail in Japanese Patent Application Publication No. 2006-160273 having been filed.

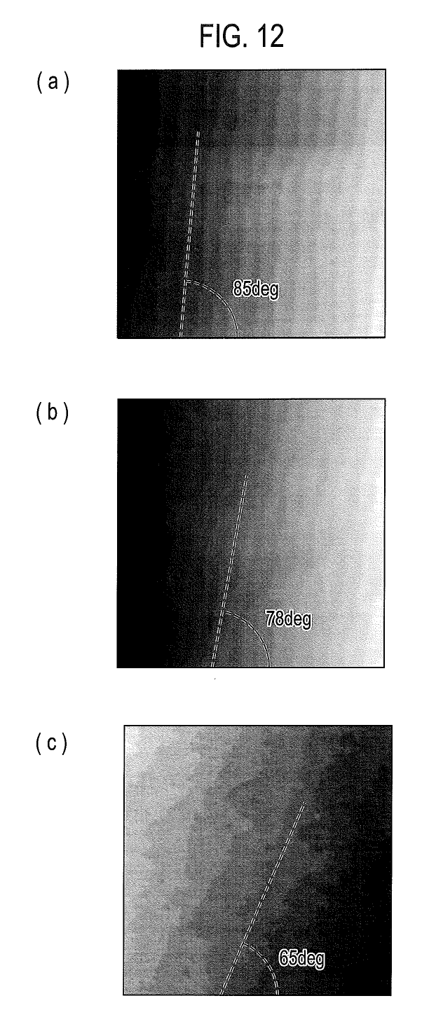

FIG. 12 shows how the step edges and the step widths change when the normal line Z to the growth surface (principal surface) has an off angle in the a-axis direction in addition to an off angle in the m-axis direction. A comparison was made by fixing the off angle Φₘ in the m-axis direction described in FIG. 11(a) at 0.4° while the off angle Φₐ in the a-axis direction is changed to a large angle. This was implemented by changing the cutout plane of the Mg_{X}Zn_{1-X}O substrate.

As the off angle Φₐ in the a-axis direction is changed to a larger angle, an angle θ_{S} formed between each step edge and the m-axis direction is also changed in a direction in which the angle θ_{S} becomes larger. So, angles of θ_{S} are described in FIG. 12. FIG. 12(a) is when θ_{S}=85°, but neither the step edges nor the step widths are disturbed. FIG. 12(b) is when θ_{S}=78° and there is a small disturbance, but the step edges and the step widths can still be recognized. FIG. 12(c) is when θ_{S}=65° and the disturbance is so severe that the step edges and the step widths can no longer recognized. If a ZnO-based semiconductor layer were epitaxially grown on the surface in the condition of FIG. 12(c), the aforementioned lateral growth would not be performed and therefore a flat film would not be formed. In the case of FIG. 12(c), θ_{S} is equivalent to 0.15° in terms of the inclination Φₐ in the a-axis direction. The above data shows that a range of 70°≦θ_{S}≦90° is desirable.

As described above, when θ_{S}=70°, it is the angle at which fine diagonal steps cannot be maintained and irregularities are formed in the step surfaces, disturbing the alignment of the step edges. Assuming that Φₘ=0.5° in this case, then Φₘ is equivalent to 0.1° in terms of the inclination Φₐ in the a-axis direction.

Meanwhile, in θ_{S}, due to a symmetric nature, there is equivalency between a case where the projection axis B of the normal line Z to the principal surface is inclined at the angle Φₐ in the a-axis direction and a case where the projection axis B is inclined in the −a-axis direction in FIG. 11(a). Therefore, some consideration is needed. When projected on the m-axis/a-axis plane while setting the inclination angle at −Φₐ, the level-difference portions formed by the step surfaces appear as shown in FIG. 11(c). The condition of an angle θᵢ between the m-axis and each step edge follows the above-described range of 70°≦θᵢ, ≦90°. Because a relation θ_{S}=180°−θᵢ, is established, the maximum value of θ_{S} is 180°−70°=110°. Thus, the range of 70°≦θ_{S}≦110° is the final condition allowing formation of a flat film.

Next, the following is when θₛ is expressed using Φₘ and Φₐ based on FIG. 11 while using radian (rad) as the unit of angle. According to FIG. 11, an angle α is expressed as:

α=arctan(tan Φₐ/tan Φₘ), and therefore

θₛ=(π/2)−α=(π/2)−arctan(tan Φₐ/tan Φₘ).

Here, when θₛ is converted from radian to degree,

θ_{S}=90−(180/π)arctan(tan Φₐ/tan Φₘ), which leads to an expression of

70≦{90−(180/π)arctan(tan Φₐ/tan Φₘ)}≦110.

Here, as is well known, tan represents tangent and arctan represents arctangent. Note that it is when θ_{S}=90° that there is no inclination toward the a-axis and only toward the m-axis. Also, when the unit of angle for Φₘ and Φₐ are expressed as Φₘ° and Φₐ° instead of radian, the above inequality is expressed as follows:

70≦{90−(180/π)arctan(tan(πΦₐ/180)/tan(πΦₘ/180))}≦110.

It is possible to stack a flat thin film by forming a principal surface of a substrate by, as described above, using a ZnO-based substrate's +C plane excellent in chemical stability and also allowing the off angle between the c-axis on the +C plane and the normal line to the principal surface of the substrate to satisfy the above relationship. Moreover, the substrate's principal surface with such specification is high in chemical thermal stability. Hence, it is easy to perform an ashing process and an ozone process, after polishing. Also, these processes can remove carbonate groups and carboxyl groups deposited on the principal surface of the substrate, and also repair the damage on the surface. Accordingly, it is possible to form a ZnO-based substrate having an extremely-high-quality crystal growth principal surface.

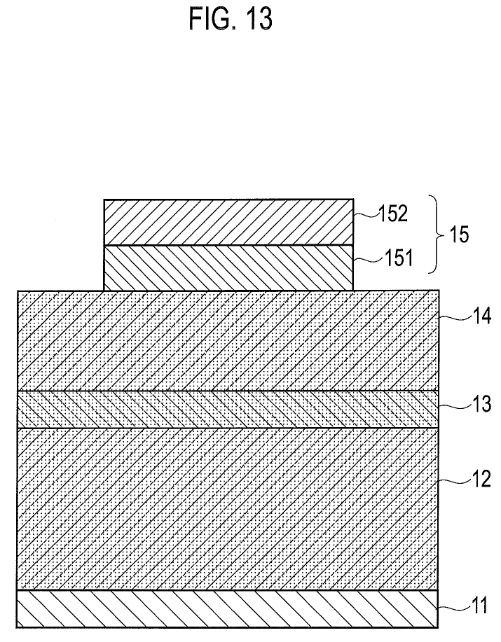

Lastly, an example of a ZnO-based semiconductor device obtained by stacking a ZnO-based thin film on the ZnO-based substrate of the present invention is shown in FIG. 13. FIG. 13 shows an example of an ultraviolet LED using a Mg_{Y}Zn_{1-Y}O film (0≦Y≦1) containing p-type impurities. The crystal growth surface was set as the principal surface having the +C plane of a ZnO substrate 12 and formed in such manner that the normal line to the principal surface was inclined slightly from the c-axis toward the m-axis. A CMP polishing process was performed to bring out a clean surface in the principal surface, followed thereafter by an ashing process or an ozone process. Then, an undoped ZnO layer 13 and a nitrogen-doped p-type MgZnO layer 14 were formed on the ZnO substrate 12 by crystal growth. Subsequently, a p electrode 15 and a n electrode 11 were formed. As shown in FIG. 13, the p electrode 15 was formed of a multilayer metal film including a Au (gold) layer 152 and a Ni (nickel) layer 151. The n electrode 11 was made of 1n (indium). The growth temperature of the nitrogen-doped MgZnO layer 14 was around 800° C.

Meanwhile, as another example of the ZnO-based semiconductor device, in the structure in FIG. 13, the undoped ZnO layer 13 may be replaced, for example, with a MQW active layer obtained by stacking a Mg_{0.1}ZnO layer having a film thickness of 7 to 10 nm and a ZnO layer having a film thickness of 2 to 4 nm alternately for several cycles. A MgZnO layer doped with approximately 0.5×10¹⁸ cm⁻³ of Ga (gallium) and having a film thickness of approximately 5 nm may be formed between 12 and 13.

1. A ZnO-based substrate, wherein any one of a carboxyl group and a carbonate group is substantially absent in a principal surface on a side where crystal growth takes place.

2. A ZnO-based substrate, wherein in X-ray photoelectron spectroscopy of a principal surface on a side where crystal growth takes place, an excitation energy peak of a 1s core electron of a carbon atom does not substantially appear within a range from 288 to 290 eV.

3. A ZnO-based substrate, wherein in X-ray photoelectron spectroscopy of a principal surface on a side where crystal growth takes place, a peak excitation energy distribution of a 1s core electron of a carbon atom in a range from 284 to 286 eV spreads from a peak energy as a center with a skirt on a high energy side that is not wider than a skirt on a low energy side.

4. The ZnO-based substrate according to any one of claims 1 to 3, wherein the ZnO-based substrate is a Mg_{X}Zn_{1-X}O substrate (0≦X<1).

5. The ZnO-based substrate according to any one of claims 1 to 3, wherein
the principal surface where the crystal growth takes place has a C-plane, and
a projection axis obtained by projecting a normal line to the principal surface onto a plane of an m-axis and a c-axis of crystal axes of the substrate is inclined toward the m-axis within a range not larger than 3°.

6. The ZnO-based substrate according to any one of claims 1 to 3, wherein
a projection axis obtained by projecting a normal line to the principal surface onto a plane of an a-axis and a c-axis of crystal axes of the substrate is inclined toward the a-axis at an angle Φₐ,
a projection axis obtained by projecting the normal line to the principal surface onto a plane of an m-axis and the c-axis at the principal surface is inclined toward the m-axis at an angle Φₘ, and
the Φₐ satisfies
70≦{90−(180/π)arctan(tan(πΦₐ/180)/tan(πΦₘ/180))}≦110.

7. A ZnO-based semiconductor device, wherein a ZnO-based thin film is stacked on the ZnO-based substrate according to any one of claims 1 to 3.

8. The ZnO-based semiconductor device according to claim 7, wherein the ZnO-based thin film is a stacked body in which a p-type MgZnO layer is stacked on an undoped ZnO layer.

9. The ZnO-based semiconductor device according to claim 7, wherein the ZnO-based thin film is a stacked body in which a n-type MgZnO layer, an active layer and a p-type MgZnO layer are stacked in this order, the active layer obtained by alternately arranging MgZnO and ZnO.

10. A method for processing a ZnO-based substrate, comprising the step of bringing any one of an oxygen radical, oxygen plasma and ozone into contact with a principal surface where crystal growth takes place, before the crystal growth is started.
